(19) United States
(12) Patent Application Publication
(10) Pub. No.: US 2026/0037701 A1
(43) Pub. Date: Feb. 5, 2026

(54) ARTIFACT DETECTION TECHNIQUES FOR BOREHOLE DATA USING REFERENCE DATA PATTERNS

(71) Applicant: Schlumberger Technology Corporation, Sugar Land, TX (US)

(72) Inventors: Eya Ghamgui, Clamart (FR); Imane Baho, Clamart (FR); Pontus Loviken, Clamart (FR); Josselin Kherroubi, Clamart (FR); Mohamed Nassar, Doha (QA); Rasesh Saraiya, Doha (QA)

(21) Appl. No.: 18/792,591

(22) Filed: Aug. 2, 2024

(51) Int. Cl. G06F 30/28; G01V 20/00

(52) U.S. Cl. CPC G06F 30/28; G01V 20/00

(57) ABSTRACT

A method includes receiving, borehole data and receiving one or more reference data patterns from a storage component. The one or more reference data patterns correspond to one or more borehole data artifacts. Further, the method includes applying the one or more reference data patterns to the borehole data to detect one or more regions in the borehole data that include a potential artifact. Even further, the method includes determining one or more artifact scores associated with the one or more regions based on a comparison between the one or more regions and the one or more reference data patterns. Even further, the method includes generating a label based on a portion of the one or more regions. The label is indicative of a respective region of the portion having an artifact score below a threshold value. Further still, the method includes generating the labeled borehole data.

### BACKGROUND

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Sometimes, boreholes will cut through natural fracture in the shape of planes. As image logs are viewed as unfolded cylinders, the natural fractures get the form of a sinusoid with a period of the width of the borehole image. These sinusoids may include any amplitude, phase, and vertical position in the well. The period is, however, for physical reasons, always the width of the image. In the case of natural fractures, these sinusoids show up as dark lines on brighter backgrounds. There are, however, other sinusoids. A boundary between two formations might show up as sinusoids separating two areas of different darkness, and resistive fractures could show up as bright sinusoids on a darker background in electromagnetic (EM) images. It may be desirable to develop techniques to detect sinusoids and other features that may result in unexpected operation of boreholes.

### BRIEF DESCRIPTION

Certain embodiments commensurate in scope with the originally claimed invention are summarized below. These embodiments are not intended to limit the scope of the claimed invention, but rather these embodiments are intended only to provide a brief summary of possible forms of the invention. Indeed, the invention may encompass a variety of forms that may be similar to or different from the embodiments set forth below.

In certain embodiments, a method includes receiving, via a processing system, borehole data. The method also includes receiving, via the processing system, one or more reference data patterns from a storage component. The one or more reference data patterns correspond to one or more borehole data artifacts. Further, the method includes applying, via the processing system, the one or more reference data patterns to the borehole data to detect one or more regions in the borehole data that include one or more potential artifacts. Even further, the method includes determining, via the processing system, one or more artifact scores associated with the one or more regions based on a comparison between the one or more regions and the one or more reference data patterns. Even further, the method includes generating, via the processing system, one or more labels based on a portion of the one or more regions, wherein each of the one or more labels is indicative of a respective region of the portion of the one or more regions having an artifact score below a threshold value. Further still, the method includes generating, via the processing system, the labeled borehole data based on the one or more labels.

In certain embodiments, a system includes a computing system comprises one or more processors. The system also includes a memory storing instructions that, when executed by the computing system cause the computing system to perform operations that include receiving borehole data; receiving one or more reference data patterns from a storage component, wherein the one or more reference data patterns correspond to one or more borehole data artifacts; applying the one or more reference data patterns to the borehole data to detect one or more regions in the borehole data that include one or more potential artifacts; determine one or more artifact scores associated with the one or more regions based on a comparison between the one or more regions and the one or more reference data patterns; generating one or more labels based on a portion of the one or more regions, wherein each of the one or more labels is indicative of a respective region of the portion of the one or more regions having an artifact score below a threshold value; and generating the labeled borehole data based on the one or more labels.

In certain embodiments, one or more tangible non-transitory computer-readable memory media include processor-executable instructions that, when executed by one or more processors, cause the one or more processors to receive borehole data; receive one or more reference data patterns from a storage component, wherein the one or more reference data patterns correspond to one or more borehole data artifacts; apply the one or more reference data patterns to the borehole data to detect one or more regions in the borehole data that include one or more potential artifacts; determine one or more artifact scores associated with the one or more regions based on a comparison between the one or more regions and the one or more reference data patterns; generate one or more labels based on a portion of the one or more regions, wherein each of the one or more labels is indicative of a respective region of the portion of the one or more regions having an artifact score below a threshold value; and generate the labeled borehole data based on the one or more labels.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 illustrates a drilling system for drilling an earth formation, in accordance with the present disclosure;

FIG. 2 illustrates a block diagram of a borehole image analysis system that may be used to analyze borehole images captured for the drilling system of FIG. 1 as described in greater detail herein, in accordance with the present disclosure;

FIG. 3 is a block diagram of an example process for utilizing borehole data with a sinusoid detection model, in accordance with the present disclosure;

FIG. 4 is a flow diagram of an example process for generating labeled borehole data, in accordance with the present disclosure;

FIG. 5 is an image of a missing value pattern, in accordance with the present disclosure;

FIG. 6A shows an image of a borehole data that includes a missing value artifact, in accordance with the present disclosure;

FIG. 6B shows a first image of identified regions within the borehole data of FIG. 6A, in accordance with the present disclosure;

FIG. 6C shows a second image of identified regions within the borehole data of FIG. 6A, in accordance with the present disclosure;

FIG. 7A shows an image of a borehole data that includes a line artifact, in accordance with the present disclosure;

FIG. 7B shows a first image of identified regions within the borehole data of FIG. 7A, in accordance with the present disclosure;

FIG. 7C shows a second image of identified regions within the borehole data of FIG. 7A, in accordance with the present disclosure;

FIG. 8A shows an image of a borehole data that includes a salt and pepper artifact, in accordance with the present disclosure;

FIG. 8B shows a first image of identified regions within the borehole data of FIG. 8A, in accordance with the present disclosure;

FIG. 9 shows borehole data having a stretching artifact, in accordance with the present disclosure;

FIG. 10A shows an example of a left-handed spiral pattern, in accordance with the present disclosure;

FIG. 10B shows an example of a right-handed spiral pattern, in accordance with the present disclosure; and

FIG. 11 shows borehole data that includes a spiral pattern and corresponding artifact scores, in accordance with the present disclosure.

### DETAILED DESCRIPTION

One or more specific embodiments of the present disclosure will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present invention, the articles “a,” “an,” “the,” and “said” are intended to mean that there are one or more of the elements. The terms “comprising,” “including,” and “having” are used in an open-ended fashion, and thus should be interpreted to mean “including, but not limited to.” Also, any use of any form of the terms “connect,” “engage,” “couple,” “attach,” or any other term describing an interaction between elements is intended to mean either an indirect or a direct interaction between the elements described. In addition, as used herein, the terms “axial” and “axially” generally mean along or parallel to a central axis (e.g., central axis of a body or a port), while the terms “radial” and “radially” generally mean perpendicular to the central axis. For instance, an axial distance refers to a distance measured along or parallel to the central axis, and a radial distance means a distance measured perpendicular to the central axis. The use of “top,” “bottom,” “above,” “below,” and variations of these terms is made for convenience but does not require any particular orientation of the components.

As mentioned above, ensuring borehole stability is desirable for maintaining expected operation and the efficiency of oil well drilling. One indicator of borehole stability are fractures. Automatic detection of these features, represented by sinusoidal curves, poses a major challenge. However, conventional techniques for identifying factures are based on visual identification by geologists. To the extent that the identification is automated, numerous factors can reduce the effectiveness of identification, leading to improper fracture identification. For example, the quality of borehole data can directly influence the clarity and fidelity of fracture curves. Due to image distortions and noise, automatic feature detection (e.g., fracture detection) is not trivial. Accordingly, it is presently recognized that it is advantageous to understand how data quality can contribute to the accuracy of automatic feature detection algorithms and the interpretation of borehole features.

Accordingly, this disclosure relates to techniques for improving the efficiency of detecting or identifying fractures using reference data patterns to remove artifacts that would lead to incorrect fracture detection or identification, and thus, may improperly inform oil and gas-related decisions (e.g., where to drill, drilling parameters, and the like). In general, the disclosed techniques include using one or more reference data patterns, such as a missing value pattern, a line artifact pattern, a salt and pepper pattern, a stretching pattern, a spiral pattern, or a combination thereof. The one or more reference data patterns correspond to artifacts that result from unexpected communication and/or electronic operations, such as data entry errors, equipment malfunctions, interruptions in data acquisition, signal interference, and the like as discussed in more detail herein. As such, a processor may compare portions of borehole data (e.g., a subset of pixels of the borehole data, a labeled region, and so on) to the one or more reference data patterns to detect one or more potential artifacts within borehole data. In some embodiments, the processor may generate an output, such as a label for generating labeled borehole data, an alert indicating borehole data that include artifacts, and the like, which may prevent the portions of the borehole data that include the artifacts from being used for feature detection or identification. In some embodiments, the processor may determine an artifact score for artifacts, and if the score exceeds a threshold, the processor may generate the output. In any case, by labeling and/or removing portions of the borehole data that includes an artifact, computational resources (e.g., memory utilization) may be preserved or otherwise not wasted since computing devices that utilize the borehole data are not utilizing the portions of the borehole data include artifacts that may increase a likelihood of improper feature detection or identification. Although this disclosure describes fracture detection, it should be noted that the disclosed techniques may also be applied to detection of other features, such as breakouts, faults, folds, beddings, and the like.

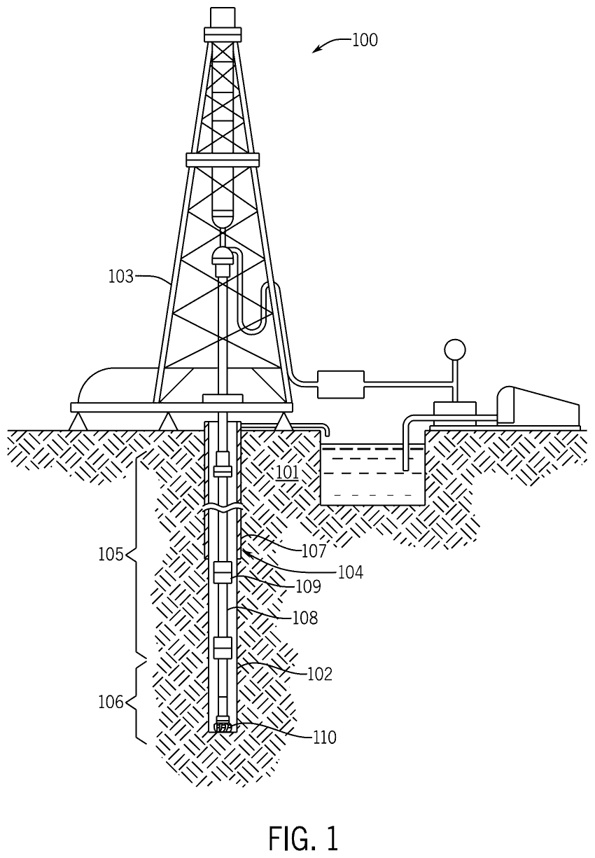

With the foregoing in mind, FIG. 1 shows one example of a drilling system 100 for drilling a geological formation 101 to form a borehole 102. The drilling system 100 includes a drill rig 103 used to support and rotate a drilling tool assembly 104 that extends downward into the borehole 102. The drilling tool assembly 104 may include a drill string 105, a bottomhole assembly (“BHA”) 106, and a bit 110, attached to the downhole end of drill string 105.

The drill string 105 may include several joints of drill pipe 108 connected end-to-end through tool joints 109. The drill string 105 transmits drilling fluid through the borehole 102 and transmits rotational power from the drill rig 103 to the BHA 106. In some embodiments, the drill string 105 further includes additional components, such as subs, pup joints, and so forth. The drill pipe 108 provides a hydraulic passage through which drilling fluid is pumped from the surface. The drilling fluid discharges through nozzles, jets, or other orifices in the bit 110 and/or the BHA 106 for the purposes of cooling the bit 110 and cutting structures thereon, and for transporting cuttings out of the borehole 102.

The BHA 106 may include the bit 110 or other components. An example BHA 106 may include additional or other components (e.g., coupled between to the drill string 105 and the bit 110). Examples of additional BHA components include drill collars, stabilizers, measurement-while-drilling (“MWD”) tools, logging-while-drilling (“LWD”) tools, downhole motors, underreamers, section mills, hydraulic disconnects, jars, vibration or dampening tools, other components, or combinations of the foregoing downhole well tools. The bit 110 may also include other cutting structures in addition to or other than a drill bit, such as milling or underreaming tools. In general, the drilling system 100 may include other drilling components and accessories, such as make-up/break-out devices (e.g., iron roughnecks or power tongs), valves (e.g., kelly cocks, blowout preventers, and safety valves), other components, or combinations of the foregoing. Additional components included in the drilling system 100 may be considered a part of the drilling tool assembly 104, the drill string 105, or a part of the BHA 106 depending on their locations in the drilling system 100.

The bit 110 in the BHA 106 may be any type of bit suitable for degrading formation or other downhole materials. For instance, the bit 110 may be a drill bit suitable for drilling the geological formation 101. Example types of drill bits used for drilling earth formations are fixed-cutter or drag bits, roller cone bits, and percussion hammer bits. In some embodiments, the bit 110 is an expandable underreamer used to expand a wellbore diameter. In other embodiments, the bit 110 is a mill used for removing metal, composite, elastomer, other downhole materials, or combinations thereof. For instance, the bit 110 may be used with a whipstock to mill into a casing 107 lining the borehole 102. The bit 110 may also be used to mill away tools, plugs, cement, and other materials within the borehole 102, or combinations thereof. Swarf or other cuttings formed by use of a mill may be lifted to surface, or may be allowed to fall downhole.

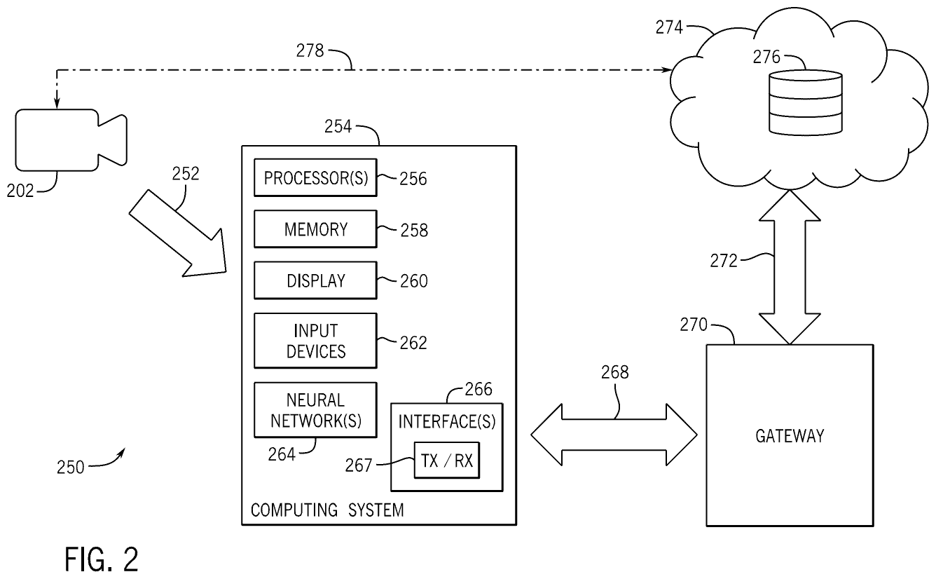

FIG. 2 is a block diagram of a borehole image analysis system 250 that may be used to analyze borehole data (e.g., borehole images or image data) captured for the drilling system 100 of FIG. 1 as described in greater detail herein. The borehole data may be received from a camera 202 as input data 252 at a computing system 254. In certain embodiments, the camera 202 may be implemented within a downhole tool (e.g., as part of a BHA 106) that may transmit the input data 252 as wired or wireless communications. In certain embodiments, the downhole tool that includes the camera 202 may include any components discussed in relation to the computing system 254. Indeed, in certain embodiments, the computing system 254 may be and/or may include the downhole tool that includes the camera 202. However, in other embodiments, the computing system 254 may be located at the surface of the drilling system 100 of FIG. 1. The various functional blocks shown in FIG. 2 may include hardware elements (including circuitry), software elements (including computer code stored on a tangible computer-readable medium), or a combination of both hardware and software elements. It should be noted that FIG. 2 is merely one example of a particular implementation and is intended to illustrate the types of components that may be present in the computing system 254.

As illustrated, the computing system 254 may include one or more processor(s) 256, a memory 258, a display 260, input devices 262, one or more neural networks(s) 264, and one or more interface(s) 266. In the computing system 254, the processor(s) 256 may be operably coupled with the memory 258 to facilitate the use of the processors(s) 256 to implement various stored programs. Such programs or instructions executed by the processor(s) 256 may be stored in any suitable article of manufacture that includes one or more tangible, computer-readable media at least collectively storing the instructions or routines, such as the memory 258. The memory 258 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor(s) 256 to enable the computing system 254 to provide various functionalities. In some embodiments, the processor(s) 256 may be capable of generating, training, or refining models (e.g., a sinusoidal or fracture detection model as described herein). For example, the processors 256 may utilize machine learning and/or neural network techniques to generate, train, or refine the models.

The input devices 262 of the computing system 254 may enable a user to interact with the computing system 254 (e.g., pressing a button to increase or decrease a volume level). The interface(s) 266 may enable the computing system 254 to interface with various other electronic devices. The interface(s) 266 may include, for example, one or more network interfaces for a personal area network (PAN), such as a Bluetooth network, for a local area network (LAN) or wireless local area network (WLAN), such as an IEEE 802.11x Wi-Fi network or an IEEE 802.15.4 wireless network, and/or for a wide area network (WAN), such as a cellular network. The interface(s) 266 may additionally or alternatively include one or more interfaces for, for example, broadband fixed wireless access networks (WiMAX), mobile broadband Wireless networks (mobile WiMAX), and so forth.

In certain embodiments, to enable the computing system 254 to communicate over the aforementioned wireless networks (e.g., Wi-Fi, WiMAX, mobile WiMAX, 4G, LTE, and so forth), the computing system 254 may include a transceiver (Tx/Rx) 267. The transceiver 267 may include any circuitry that may be useful in both wirelessly receiving and wirelessly transmitting signals (e.g., data signals). The transceiver 267 may include a transmitter, a receiver, or a transmitter and a receiver combined into a single unit.

The input devices 262, in combination with the display 260, may allow a user to control the computing system 254. For example, the input devices 262 may be used to control/initiate operation of the neural network(s) 264. Some input devices 262 may include a keyboard and/or mouse, a microphone that may obtain a user's voice for various voice-related features, and/or a speaker that may enable audio playback. The input devices 262 may also include a headphone input that may provide a connection to external speakers and/or headphones.

In certain embodiments, the neural network(s) 264 may include hardware and/or software logic that may be arranged in one or more network layers. In certain embodiments, the neural network(s) 264 may be used to implement machine learning and may include one or more suitable neural network types. For instance, the neural network(s) 264 may include a perceptron, a feed-forward neural network, a multi-layer perceptron, a convolutional neural network, a long short-term memory (LSTM) network, a sequence-to-sequence model, and/or a modular neural network. In some embodiments, the neural network(s) 264 may include at least one deep learning neural network.

As discussed below, the output of the neural network(s) 264 may be based on the input data 252, such as metrics used to identify sinusoids in borehole images, as described in greater detail herein. This output may be used by the computing system 254. Additionally or alternatively, the output from the neural network(s) 264 and/or the processor(s) 256 may be transmitted using a communication path 268 from the computing system 254 to a gateway 270. The communication path 268 may use any of the communication techniques previously discussed as available via the interface(s) 266. For instance, the interface(s) 266 may connect to the gateway 270 using wired (e.g., Ethernet) and/or wireless (e.g., IEEE 802.11) connections. The gateway 270 couples the computing system 254 to a wide-area network (WAN) connection 272, such as the Internet. The WAN connection 272 may couple the computing system 254 to a cloud network 274. The cloud network 274 may include one or more computing systems 254 grouped into one or more locations (e.g., data centers). The cloud network 274 includes one or more databases 276 that may be used to store the output of the neural network(s) 264. Indeed, in some embodiments, the camera 202 (or the computing device that the camera 202 is a part of) may send the input data 252 to the cloud 274 via connection 278 (e.g., Wi-Fi, cellular, and/or Internet connections). In such embodiments, the computing system 254 may be implemented in the cloud 274. Additionally or alternatively, at least some of the processing may be performed in the computing device that includes the camera 202. In some embodiments, the cloud network 274 may perform additional transformations on the data using its own processor(s) 256 and/or neural network(s) 264. As such, all of the following steps discussed as performed in the computing system 254 may be performed in a computing system 254 that includes the camera 202 (e.g., computing device 206), a computing system 254 that is separate from but receives image/video from the camera 202, the cloud network 274, and/or any other suitable computing devices.

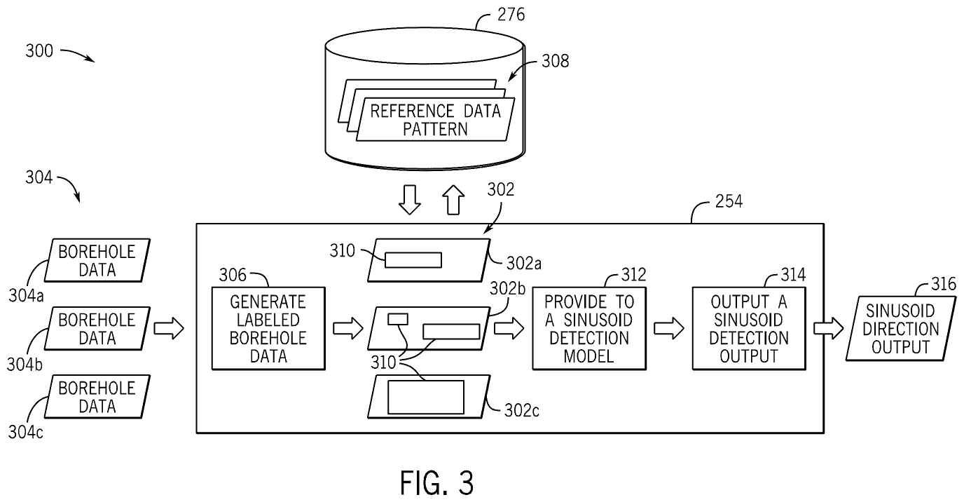

As discussed herein, it may be advantageous to utilize one or more reference data patterns to detect or identify artifacts (e.g., or potential artifacts) within portions of the borehole data and generate an output that prevents the artifacts (e.g., the portions of the borehole data that include the artifacts) from being used to detect or identify fractures. To generally illustrate this, FIG. 3 shows a data flow diagram of an example computer implemented method 300 for generating labeled borehole data 302. In general, certain process blocks performed in the method 300 may be performed by the processor 256 of the computing system 254. Moreover, certain process blocks described below may be performed in a different order than that illustrated, and, indeed, in some embodiments, certain process blocks may be skipped altogether. For simplicity, the method 300 is described as being performed by the computing system 254.

As shown, the computing system 254 receives borehole data 304a, 304b, and 304c (e.g., collectively, borehole data 304). In some embodiments, the computing system 254 may receive the borehole data from the camera 202 as input data 252. In some embodiments, the computing system 254 may receive the borehole data from a downhole tool (e.g., part of the BHA 106 described in FIG. 1). In some embodiments, the computing system 254 may receive the borehole data from a storage component, such as the one or more databases 276, the memory 258, or another suitable storage component.

At block 306, the computing system 254 generates the labeled borehole data 302a, 302b, and 302c (e.g., collectively, labeled borehole data 302). In general, the computing system 254 may generate the labeled borehole data 302 using reference data patterns 308. As shown, the reference data patterns 308 are stored within the database 276. However, the reference data patterns 308 may be stored in any suitable storage component, such as the memory 258 of the computing system 254, a cloud database, and so on.

The reference data patterns 308 may facilitate the computing system 254 in detecting or identifying certain artifacts in borehole data 304, such as a missing value artifact, a line artifact, a salt and pepper artifact, a stretched data artifact, a spiral artifact, or a combination thereof. In general, it is presently recognized that the artifacts may result from a particular type of unexpected communication operation or electrical operation of the downhole tool. This is discussed in further detail in FIG. 3, with respect to block 326. For example, the missing value artifact may result from data entry errors, equipment malfunctions. Further, the line artifact may result from generally similar unexpected operations. The salt and pepper artifact (e.g., impulse noise) may result from abrupt, intense disturbances in the image signal. The stretched data artifact may result from interruptions in data acquisition, inconsistencies in logging tool movement or variations in measured subsurface properties. The spiral artifact may also result from unexpected operation of downhole tools or during data acquisition. In any case, it is presently recognized that the presence of one or more of these artifacts in borehole data 304 may result in an inefficient use of computational resources, as a processor may improperly identify features (e.g., fractures) using the artifacts, although the feature may not actually exist. At least in some instances, it may be advantageous to still use borehole data even if the borehole data 304 includes artifacts. For example, it may be difficult or otherwise inefficient (e.g., and utilize further computational resources) to re-acquire the borehole data using a downhole tool.

To indicate the artifacts, the labeled borehole data 302 includes labels 310. In general, the labels indicate one or more portions (e.g., one or more first portions) of the labeled borehole data 302 that include artifacts and/or one or more additional portions (e.g., one or more second portions) of the labeled borehole data 302 that do not include artifacts. In some embodiments, the labels may 310 may be data, such as metadata, that specifies one or more subsets of pixels that includes artifacts, potentially includes articles, does not include artifacts, or a combination thereof. As such, the labels 310 may indicate certain portions of the labeled borehole data 302 that may be undesirable to provide as input or otherwise analyze using a model (e.g., a sinusoidal detection model), such as the portions of the labeled borehole data 302 that include artifacts. Further, the labels 310 may identify the portions that may be desirable to provide as input to the model, such as the portions of the labeled borehole data 302 that do not include an identified artifact, or otherwise an artifact that may cause an improper detection of a fracture.

At block 312, the computing system 254 provides the labeled borehole data 302 to a sinusoidal detection model, or otherwise a fracture detection model. In general, the sinusoidal detection model may utilize identified patterns (e.g., amplitudes, phase, vertical position, and the like) of values of the labeled borehole data 302 that may indicate a natural facture within a borehole. Using the labels 310 of the labeled borehole data 302, the computing system 254 may indicate which portions of the labeled borehole data 302 that the model should not use to determine the presence of a sinusoid. In this way, the labeled borehole data 302 may prevent computational resources from being wasted, and thus the computational resources may be used to perform other tasks, such as more quickly determining the presence of a sinusoid or other computational operations. In some embodiments, the computing system 254 may utilize the labeled borehole data 302 to train the sinusoidal detection model.

At block 314, the computing system 254 outputs a sinusoid detection output 316. In general, the computing system 254 may receive the sinusoid detection output 316 from the model and/or generate the sinusoid detection output 316 based on an output from the model. For example, the computing system 254 may receive an output indicating that a set of borehole data 304 (e.g., using the labeled borehole data 302 that corresponds to the borehole data 304) indicates the presence of a natural fracture. Accordingly, the computing system 254 may generate an alert, such as a visual and/or audio notification, of the borehole where a fracture or other feature is present. In some embodiments, the computing system 254 may perform a control adjustment. For example, performing the control adjustment may include the computing system 254 outputting a control signal that causes one or more components within the borehole to halt operation or otherwise close off one or more valves proximate to the fracture. In this way, generating labeled borehole data 302 may facilitate detection of features (e.g., natural fractures) and improve the speed at identifying such features.

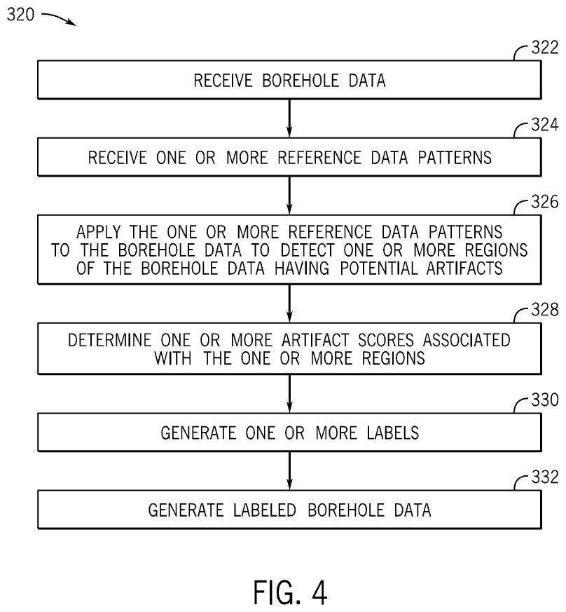

As described above, the computing system 254 may generate labeled borehole data 302. To illustrate this, FIG. 4 is a flow diagram of an example computer implemented method 320 for generating the labeled borehole data 302, according to one or more embodiments of this disclosure. In general, certain process blocks performed in the method 320 may be performed by the processor 256 of the computing system 254. Moreover, certain process blocks described below may be performed in a different order than that illustrated, and, indeed, in some embodiments, certain process blocks may be skipped altogether.

At block 322, the processor 256 receives, retrieves, or otherwise obtains borehole data 304. In general, the processor 256 may perform block 322 in a generally similar manner as described in FIG. 3 with respect to receiving the borehole data 304. For example, the processor 256 may receive the borehole data from the camera 202 as input data 252. In some embodiments, the processor 256 may receive the borehole data from a downhole tool (e.g., part of the BHA 106 described in FIG. 1). In some embodiments, the processor 256 may receive the borehole data from a storage component, such as the one or more databases 276, the memory 258, or another suitable storage component.

At block 324, the processor 256 retrieves, receives, or otherwise obtains one or more reference data patterns 308. In general, the processor 256 may retrieve the reference data patterns 308 from a storage component, such as the one or more databases 276, the memory 258, or another suitable storage component. As used herein, the “reference data patterns” include a shape (e.g., kernel) or patterns of data values that correspond to a particular type of artifact (e.g., a missing value artifact, a line artifact, a stretched data artifact, a salt and pepper artifact, and other artifacts discussed herein). In some embodiments, the processor 256 may retrieve only a subset of the reference data patterns. That is, at least in some instances, it may desirable for the processor 256 to detect only certain artifacts. For example, the processor 256 may receive an input provided by a user or an input determined by the processor 256 based on previous analysis using borehole data obtained by the same tool, from a similar geographic region, and the like, indicating a particular set of reference data patterns.

At block 326, the processor 256 applies the one or more reference data patterns to the borehole data (e.g., received at block 322) to detect one or more regions of the borehole data having potential artifacts. As discussed herein, the one or more reference data patterns may correspond to a particular type of artifact. Several non-limiting examples of artifacts and correspond reference data patterns are described in detail below.

### Missing Value Artifact

For example, the one or more reference data patterns may include a missing value pattern that correspond to a missing value artifact. As referred to herein, a “missing value artifact” in data refers to the absence of values for certain areas in image log. The missing value artifact may occur for various reasons, such as data entry errors, equipment malfunctions, and so on. It is recognized that missing values may be identified or noticed by the processor 256. For example, the missing value artifact might stand out as unusual, out of distribution, null values such as “nan” or “−9999” within the image. A second reason is that the missing value artifact may blend into the background, appearing as bright areas in the image, as discussed in more detail in FIG. 6.

Detecting missing value artifacts that blend into the background is relatively more difficult due to, for example, the similarity in the intensity of missing values to background in certain portions of the borehole data. However, it is presently recognized that missing value artifacts may exhibit shapes (e.g., rectangles, lines, etc.) that are not expected to be present in borehole data.

One specific non-limiting example of detecting missing value artifacts is described below. For example, applying the one or more reference data patterns to the borehole data when the one or more reference data patterns include missing value patterns (e.g., to detect missing value artifacts) includes applying a thresholding technique to the borehole data. For example, the thresholding technique may convert pixels having a value above or below a threshold to a single number. For example, if the range of values of borehole data are between 1-100, all pixel values 70 or greater, 80 or greater, 90 or greater, 95 or greater, may be converted to 100. This may emphasize bright areas, which may facilitate detection of missing value artifacts. Moreover, the processor 256 may identify clusters of pixels based on the similarity of the pixel values. As such, the clusters may be the regions discussed herein.

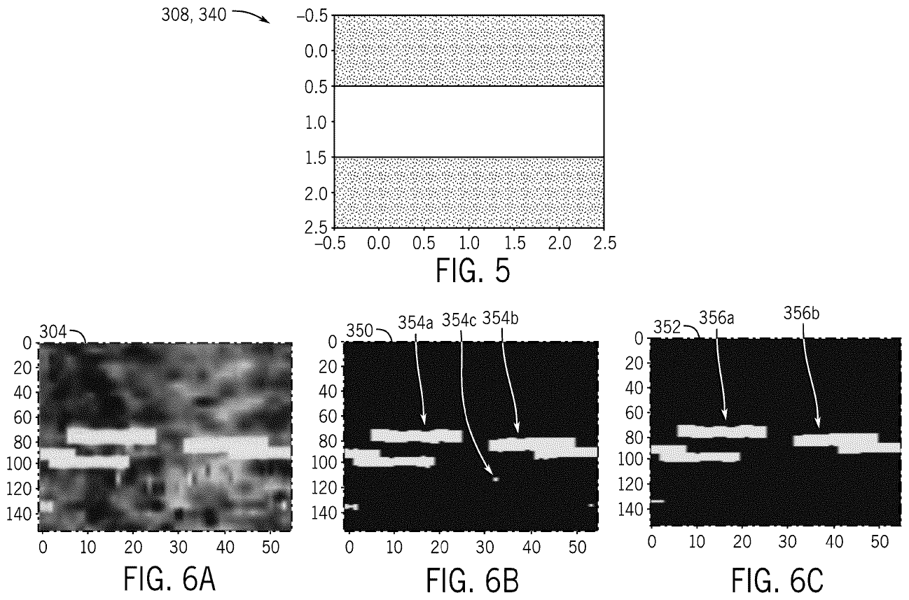

Additionally or alternatively, applying the one or more reference data patterns to the borehole data when the one or more reference data patterns include missing value patterns includes filtering out isolated pixels and regions of the resulting image that may not correspond to missing value artifacts. For example, the processor 256 may determine a region does not correspond to a missing value artifact if the shape of the region does not match the missing value pattern above or below a threshold. Several techniques could be employed for this purpose, including contour detection, morphological operations, and line detection. It is presently recognized that morphological operations offer high flexibility in detecting different shapes, based on the choice of the kernel. By selecting the appropriate kernel type (e.g., square, line, rectangle), the processor 256 may target specific regions of pixels in the borehole data having a shape that corresponds to missing value artifacts. As described in more detail in FIG. 5, the kernel may a rectangle or horizontal feature.

After removing regions that do not correspond to the missing value artifacts, the processor 256 may determine an artifact score for each region. For example, the processor 256 may determine the artifact score for a missing value artifact (e.g., a missing value artifact score) based on the percentage of total missing values per row.

### Line Artifact

As another non-limiting example, the one or more reference data patterns may include a line artifact pattern that correspond to a line artifact (e.g., a dark line artifact). As referred to herein, a “line artifact” in data refers to non-geological features present in borehole images. In some embodiments, to detect a line artifact, the processor 256 may apply a thresholding technique to the borehole data. For example, the thresholding technique may convert pixels having a value above a threshold to a single number. In some instances, it may be advantageous to preserve all or relatively most of the relevant dark information present in the image.

Further, after applying the thresholding technique, the processor 256 may apply a filtering technique to preserve horizontal lines. In general, the filtering technique may be similar to what was described with respect to detecting missing value artifacts. However, the kernel may be different. As referred to here, the “kernel” refers to a modeling component (e.g., software modeling component) that may be defined according to the form of the object (e.g., the artifact) that is desirable to detect. For example, to detect an artifact having a rectangular shape, it may be advantageous to define the kernel as a rectangle. For example, the new kernel may be selected to capture dark lines more efficiently and filter out all unnecessary detected areas. In some embodiments, the kernel is a horizontal line, but with different shape proportions to detect only very large horizontal objects. After detecting potential line artifacts, the processor 256 may apply an error rate criterion to determine whether to confirm the presence of line artifacts in the labeled borehole data 302. For example, the values of this artifact score are either 0 (no artifacts) or 1 (artifacts).

Accordingly, in some embodiments, to detect a missing value artifact and/or a line artifact, the processor 256 may apply a thresholding technique to borehole data, thereby producing or generating modified borehole data (e.g., adjusted borehole data). Further, the processor 256 may identify one or more regions within the modified borehole data. Then, the processor may determine whether a shape of the one or more regions matches a reference data pattern having a shape that corresponds to a particular artifact.

### Salt and Pepper Artifact

As another non-limiting example, the one or more reference data patterns may include a salt and pepper pattern (e.g., an impulse noise pattern) that corresponds to a salt and pepper artifact, or impulse noise artifact. As referred to herein, a “salt and pepper artifact” or “impulse noise artifact” refers to random distributions of pixels having significantly higher pixel values than neighboring pixels. For example, pixels resulting from the “impulse noise artifact” may be 5 times, 10 times, or 20 times greater than neighboring pixels. In any case, it is presently recognized that the impulse noise artifact reduces the clarity of the information contained in the borehole data. As such, the presence of salt and pepper artifacts may complicate the detection of sinusoidal patterns in the image due to abrupt changes in intensity values that can mask crucial sinusoidal details and lead to the generation of false positives.

Certain techniques for removing salt and pepper artifacts or impulse noise artifacts include using the peak signal-to-noise ratio (PSNR) as a measure to identify the salt and pepper artifacts and/or using filtering techniques. It is presently recognized that median filtering may be advantageous for detecting salt and pepper artifacts and/or impulse noise artifacts. Further, it is recognized that applying smooth techniques (e.g., after applying median filtering techniques) may refine the density scores over the whole image. This enhancement allows for the definition of density values on a per-patch basis. Increased scores correspond to higher densities of noise

### Stretching Artifact

As another non-limiting example, the one or more reference data patterns may include a stretching pattern that corresponds to stretching artifact. Stretching in borehole data is characterized by sections of logging data that appear elongated or distorted in comparison with the surrounding areas. This stretching effect can be caused by various factors, such as interruptions in data acquisition, inconsistencies in logging tool movement or variations in measured subsurface properties. These stretched areas can sometimes appear as uniform zones with constant elongation, or as regions with repeated patterns or anomalies.

The presence of stretching in drilling data can affect the interpretation of geological features and properties. Understanding the causes and characteristics of stretching may provide accurate analysis and interpretation of subsurface data for geological or engineering purposes. In addition, the detection of stretched zones may facilitate for the detection of sinusoids, as these structures can distort the sinusoidal patterns present in the data.

In some embodiments, to detect the stretching artifact, the processor 256 may define a sliding window for the algorithm. It is advantageous for the sliding window size to not be larger than the stretched areas or too small to distinguish stretches from small variations. For example, the stretching pattern may be a linear interpolation between the first and last row of the patch (e.g., one or more pixels within the sliding window) to create the stretching pattern. For example, it should be noted that, in some instances, when a zone started at a depth y0 and progressed to a depth y1, the intermediate lines between y0 and y1 could be predicted as an interpolation of the y0 and y1 lines. As such, the processor 256 may navigate through the image using a sliding window mechanism. In some embodiments, for each step, the processor 256 may generate the pattern as defined above. After that, the processor 256 may calculate the difference between the sliding window and the stretching pattern. Then, the processor 256 may compute the standard deviation per column. In some embodiments, the processor 256 may average all the variations to obtain the error value.

### Spiral Artifact

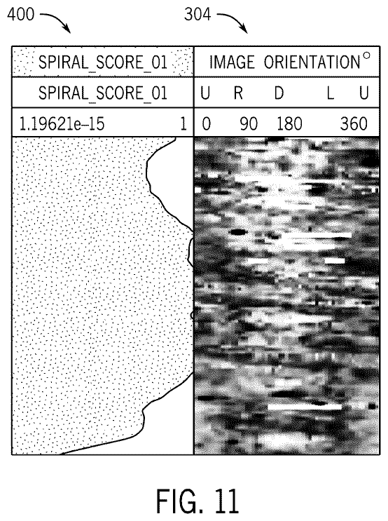

Borehole Spiraling is a common artifact in borehole images, which show up as diagonal lines over the image and can lead to errors in interpretation. This is generally shown and discussed in more detail in FIG. 11. To detect the spiral artifacts, the processor 256 may identify regions of the borehole data having a predetermined amplitude, phase, and amplitude. In some embodiments, to detect the spiral artifact, the processor 256 may apply a right-handed pattern and a left-handed pattern corresponding to a spiral pattern to the borehole data. Further, the processor 256 may detect the one or more regions based on at least a partial match between the right-handed pattern or the left-handed pattern. In some embodiments, there may be no limitation if the actual spirals are shifted along the x axis or has a steeper or shallower slope than the patterns. As such, the processor 256 may rescale the pattern along the y-axis as well as shift it along the x-axis, to detect any such fit. Certain techniques may be unable to distinguish between left-handed and right-handed slopes. As such, it may be advantageous to use both the right-handed pattern and the left-handed pattern corresponding to a spiral pattern.

To detect the spiral pattern, in some embodiments, the processor 256 may run the patterns over the borehole image, which may lead to two similarity matrices sᵣ telling and sₗ, with “r” and “l” for left-handed and right-handed. These matrices are 3-dimensional and may indicate the fit of the pattern for each depth, phase, and amplitude.

In an embodiment the phase or of the amplitude are not used, the processor 256 may only utilize the maximum similarity score of each depth, updating sᵣ and sₗ so that they become 1-dimensional with one value/true vertical depth (tvd). Although described in terms of tvd, it should be noted that the processor 256 may utilize a maximum similarity score of each depth, updating sᵣ and sₗ so that they become 1-dimensional with one value/measured depth (md) or another type of depth measurement. It is presently recognized that a spiral pattern may not occur twice at the same time, as that would not be a spiral but, for example, a sinusoid that is going down on one side and coming back up on the other one. To eliminate such sections from the spiral pattern, it may be advantageous to utilize a single similarity vector s=|sᵣ−sₗ|.

To provide a spiral score that reflects spiraling that is pervasive over some given depth, it may be advantageous to average the scores so that the score for each depth is the average over some window, for example 100 pixels. The processor 256 may analyze the artifact scores over wells to find a threshold sₘₐₓ, above which actual spiraling behavior is near certain. Then, the processor 256 may divide the spiral scores by this value and put all values above it to 1, so that:

$$s ← min ( \frac{s}{{s}_{max}} , 1 )$$

As such, the processor 256 may obtain a spiral score s that provides a flag for spiraling whenever reaching 1 and indicates that there is no spiraling when close to 0. Values in-between may be seen as some intrinsic uncertainty level. As such, it may be desirable to generate an alert indicating that additional review or input is desirable.

At block 328, the processor 256 determines one or more artifact scores associated with the one or more regions of the borehole data having potential artifacts. In general, the artifact score is a numerical representation indicating a likelihood that the borehole data or at least one of the one or more regions includes an artifact. For example, the processor 256 may determine an artifact score within a range of artifact score values. The relative value of the artifact score with respect to the range of artifact score values may indicate whether a potential artifact is an actual artifact, not an artifact, or that it may be desirable to perform additional analysis on the artifact region, as discussed in more detail herein. Certain artifact scores are discussed above in the description of block 326.

In some embodiments, the processor 256 may determine a respective artifact score for each of the one or more regions that include a potential artifact. For example, if the processor 256 detected five regions of the borehole data as having potential artifacts, the processor 256 may determine five artifact scores. It should be noted that although this example relates to five regions and/or five artifact scores, any number of regions may be detected and/or any number of artifact score may be detected, such as 1, 2, 3, 4, 5, or more than 5 artifact scores. In some embodiments, the artifact score may be a composite artifact score. For example, the composite artifact score may be a single artifact score for one borehole data.

In some embodiments, the processor 256 may apply a first reference data pattern (e.g., at block 326) and then proceed to block 328 to determine a first artifact score for the first reference data. If the first artifact score is within a threshold range, or a first threshold range, (e.g., indicating that it may be desirable for further review by the processor 256 to determine whether a region includes a potential artifact), the processor 256 may return back to block 326 and apply a second reference data pattern and, ultimately, determine a second artifact score (e.g., an additional artifact score). If the second artifact score is within the threshold range, or a second threshold range, the processor 256 may return back to block 326 for a third reference data, a fourth reference data, a fifth reference data, or a combination thereof. However, if the first artifact score, the second artifact score, or any subsequent artifact score is outside of the threshold range or otherwise indicates that the potential artifact in the region is likely an artifact, the processor 256 may proceed to block 330.

In some embodiments, the processor 256 may determine the artifact score based on a relative area or a number of pixels within the regions corresponding to the potential artifact. For example, if the one or more regions including the artifact include 40% or more, 50% or more, 60% or more, 70% or more, 80% or more, or 90% or more of the total area or number of pixels of the borehole data, the processor 256 may further increase the artifact score or, in some instances, assign an artifact score that the borehole data should not be used or otherwise reviewed by an operator.

At block 330, the processor 256 generates one or more labels for the one or more regions of the borehole data based on the one or more artifact scores. As described herein, the labels may indicate a portion (e.g., a first potion) of the one or more regions of the borehole data have artifacts and/or that an additional portion (e.g., a second portion) do not include artifacts. In some embodiments, the portion may be at least 1, at least 2, or at least 3 of the one or more regions, or 30%, 50%, 70%, or 90% of the one or more regions. In any case, label may indicate a particular subset of pixels (e.g., a range of pixels, an area of pixels, a set of pixel numbers, and the like) that include artifacts or do not include artifacts.

At block 332, the processor 256 generates labeled borehole data 302. As discussed with respect to FIG. 3, the labeled borehole data 302 includes one or more labels 310 that indicate that it may be undesirable for the one or more regions having artifact scores corresponding to actual artifacts to be used in fracture detection.

As described herein, the one or more reference data patterns 308 may include a missing data pattern. To illustrate this, FIG. 5 shows a reference data pattern 308 that is a missing data pattern 340. In the illustrated embodiment, the missing data pattern 340 is a horizonal line kernel. The missing data pattern 340 includes white portions that correspond to pixels having a value above a threshold. Further, the missing data pattern 340 black portions that correspond to pixels having a value below a threshold. Accordingly, the missing data pattern 340 may be applied as a mask to identify the regions that include artifacts. Although illustrated as a rectangle, the shape of the missing data pattern 340 may be any suitable shape, such as oval-shaped, circular-shaped, square-shaped, and the like.

To illustrate how the missing data pattern 340 may be used to identify artifacts, FIGS. 6A, 6B, and 6C (e.g., FIGS. 6A-6C) shows borehole data 304, an image 350, and an image 352. The borehole data 304 of FIG. 6A includes missing value regions. The image 350 of FIG. 6B shows identified regions 354a, 354b, and 354c (e.g., collectively 354). In general, the regions 354a, 354b, and 354c may be detected in a generally similar manner as described in block 326 of FIG. 4. For example, the processor 256 may apply the missing data pattern 340 of FIG. 5 and determine areas or a subset of pixels that match the missing data pattern 340 within a threshold similarity, such as 50% or greater match, 60% or greater match, 70% or greater match, 80% or greater match, or 90% or greater match. The image 352 of FIG. 6C illustrate regions 356a and 356b that include artifacts or otherwise correspond to regions 354 that have an artifact score above an artifact score threshold. For example, as shown, the image 352 includes region 356a that corresponds to region 354a and region 356b that corresponds to 354b. The image 352 does not include a region 356 that corresponds to the region 354c. As such, region 354c represents a region 354 having an artifact score in a threshold range that does not correspond to the region 354 having an artifact. Accordingly, the processor 256 may generate labels indicating that at least the region 356a and 356b (e.g., or regions 354a and 354b) include missing value artifacts.

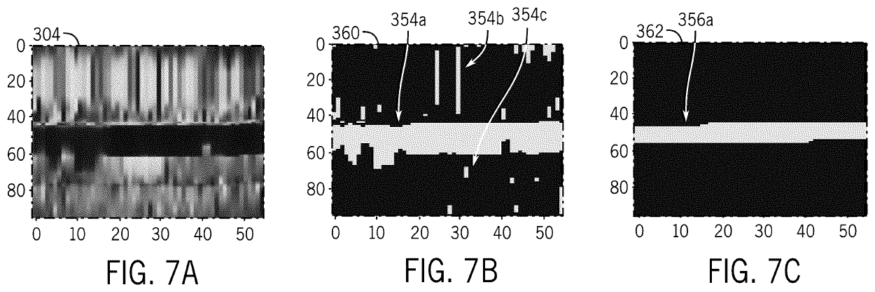

In some embodiments, the reference data pattern 308 may be a line artifact pattern. In some embodiments, the line artifact pattern represents a range of the borehole data where an acquisition interruption may have occurred. To illustrate this, FIGS. 7A, 7B, and 7C (e.g., FIGS. 7A-7C) show a borehole data 304, an image 360, and an image 362. The borehole data 304 of FIG. 7A includes a line artifact. The image 360 of FIG. 7B shows identified regions 354a, 354b, and 354c (e.g., collectively 354). In general, the regions 354a, 354b, and 354c may be detected in a generally similar manner as described in block 326 of FIG. 4. For example, the processor 256 may apply the reference data pattern 308 that is a line artifact pattern to the borehole data 304 and determine areas or a subset of pixels that match the line artifact pattern within a threshold similarity, such as 50% or greater match, 60% or greater match, 70% or greater match, 80% or greater match, or 90% or greater match. The image 362 of FIG. 7C illustrate regions 356a and 356b that include artifacts or otherwise correspond to regions 354 that have an artifact score above an artifact score threshold. For example, as shown, the image 352 includes region 356a that corresponds to region 354a. The image 352 does not include a region 356 that corresponds to the region 354b or region 354c. As such, region 354c and the region 354b represents regions 354 having an artifact score in a threshold range that does not correspond to the region 354 having an artifact. Accordingly, the processor 256 may generate a label indicating that at least the region 356a (e.g., or region 354a) includes a line artifact.

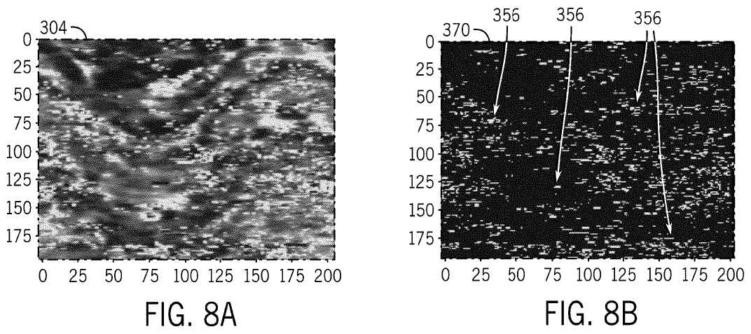

In some embodiments, the reference data pattern 308 may be a salt and pepper pattern. To illustrate this, FIGS. 8A and 8B show a borehole data 304 and an image 370. In general, the borehole data 304 includes noise, such as a random distribution of black and white pixels. As described with respect to block 326 of FIG. 4, the processor 256 may identify the salt and pepper pattern by detecting variations in the intensity values of the pixels. For example, the processor 256 may apply a median filtering to detect noise within the borehole data. Further, the processor 256 may detect the one or more regions that correspond to the salt and pepper noise (e.g., salt and pepper artifact) based on the detect noise having values that exceed a noise threshold.

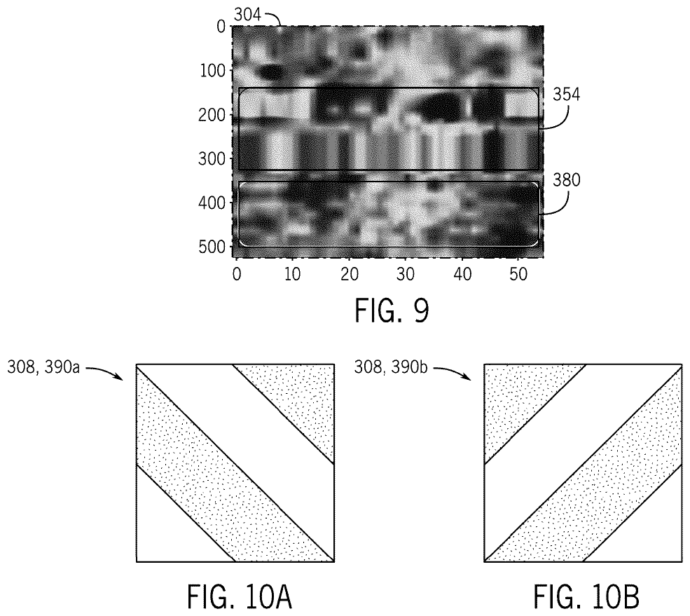

In some embodiments, the reference data pattern 308 may be a stretched pattern. To illustrate this, FIG. 9 shows borehole data 304 including region 354 that includes a stretched artifact. Additionally, the borehole data 304 includes a region 380 that indicates a region that does not include an artifact. As described with respect to block 326 of FIG. 4, the processor 256 may identify the stretched pattern by identifying regions that are elongated. For example, the processor 256 may predict a pattern of the borehole data 304 based on a linear interpolation between two regions (e.g., the two boundaries) of the borehole data 304. Further, the processor 256 may detect the one or more regions 354 based on a mismatch between data of the one or more regions 354 and the predicted pattern of the borehole data 304.

As described herein, the one or more reference data patterns 308 may include a spiral pattern. To illustrate this, FIG. 10A shows a reference data pattern 308 that is a left-handed spiral pattern 390a. Further, FIG. 10B shows a reference data pattern 308 that is a right-handed spiral pattern 390b. In general, the processor 256 may identify both left-handed spiral patterns and right-handed spiral patterns in a generally similar manner as described with respect to block 326 of FIG. 4. To illustrate how the left-handed spiral pattern 390a and the right-handed spiral pattern 390b may be used to identify artifacts, FIG. 11 shows borehole data 304 and a calculated spiral score log 400. In general, the calculated spiral score log 400 indicates a spiral artifact score (e.g., ‘1’ indicating the presence of the spiral artifact and ‘0’ indicating the absence of the spiral artifact). Accordingly, the processor 256 may identify certain regions based on the spiral score being above or below a threshold value, such as 0.4, 0.5, 0.6, 0.7, 0.8, and the like.

Technical effects of this disclosure include techniques for reducing computational resources used for operations that may lead to false positives. For example, it is presently recognized that the presence of one or more of these artifacts in borehole data may result in an inefficient use of computational resources, as a processor may improperly identify features (e.g., fractures) using the artifacts, although the feature may not actually exist. Accordingly, by labeling the borehole data before the borehole data is utilized by the model, the disclosed techniques may prevent computational resources from being wasted, and thus the computational resources may be used to perform other tasks, such as more quickly determining the presence of other borehole features in other borehole data.

A method, comprising: receiving, via a processing system, borehole data; receiving, via the processing system, one or more reference data patterns from a storage component, wherein the one or more reference data patterns correspond to one or more borehole data artifacts; applying, via the processing system, the one or more reference data patterns to the borehole data to detect one or more regions in the borehole data that include one or more potential artifacts; determining, via the processing system, one or more artifact scores associated with the one or more regions based on a comparison between the one or more regions and the one or more reference data patterns; generating, via the processing system, one or more labels based on a portion of the one or more regions, wherein each of the one or more labels is indicative of a respective region of the portion of the one or more regions having an artifact score below a threshold value; and generating, via the processing system, labeled borehole data based on the one or more labels.

The method of any preceding clause, further comprising generating a sinusoid detection model based on the labeled borehole data.

The method of any preceding clause, wherein generating the sinusoid detection model comprises training the sinusoid detection model using an additional portion of the one or more regions, wherein each region of the additional portion of the one or more regions has an additional artifact score above the threshold value.

The method of any preceding clause, wherein applying the one or more reference data patterns to the borehole data comprises: applying a thresholding technique to the borehole data to generate adjusted borehole data; identifying one or more clusters of the adjusted borehole data having null values based on a missing value pattern, wherein the one or more reference data patterns comprise the missing value pattern; and detecting the one or more regions based on the one or more clusters of the adjusted borehole data having the null values.

The method of any preceding clause, wherein applying the one or more reference data patterns to the borehole data comprises: applying a thresholding technique to the borehole data to generate adjusted borehole data; and identifying the one or more regions having a shape that matches a line artifact pattern, wherein the one or more reference data patterns comprise the line artifact pattern.

The method of any preceding clause wherein applying the one or more reference data patterns to the borehole data comprises: applying a right-handed pattern and a left-handed pattern corresponding to a spiral pattern to the borehole data, wherein the one or more reference data patterns comprise a spiral pattern; and detecting the one or more regions based on at least a partial match between the right-handed pattern or the left-handed pattern.

The method of any preceding clause, wherein applying the one or more reference data patterns comprises to the borehole data comprises: predicting pattern of the borehole data based on a linear interpolation between two regions of the borehole data, wherein the one or more reference data patterns comprise a stretching pattern; and detecting the one or more regions based on a mismatch between data of the one or more regions and the predicted pattern of the borehole data.

The method of any preceding clause, wherein applying the one or more reference data patterns to the borehole data comprises: applying a median filtering to detect noise within the borehole data, wherein the one or more reference data patterns comprise a salt and pepper pattern; and detecting the one or more regions based on the detect noise having values that exceed a noise threshold.

A system, comprising: a computing system comprises one or more processors; a memory storing instructions that, when executed by the computing system, are configured to cause the computing system to perform operations comprising: receiving borehole data; receiving one or more reference data patterns from a storage component, wherein the one or more reference data patterns correspond to one or more borehole data artifacts; applying the one or more reference data patterns to the borehole data to detect one or more regions in the borehole data that include one or more potential artifacts; determining one or more artifact scores associated with the one or more regions based on a comparison between the one or more regions and the one or more reference data patterns; generating one or more labels based on a portion of the one or more regions, wherein each of the one or more labels is indicative of a respective region of the portion of the one or more regions having an artifact score below a threshold value; and generating labeled borehole data based on the one or more labels.

The system of any preceding clause, wherein the instructions that, when executed by the computing system, are configured to cause the computing system to apply the one or more reference data patterns by applying a thresholding technique to borehole data to produce a modified borehole data; identifying the one or more regions within the modified borehole data; and determining whether a shape of the one or more regions matches the one or more reference data patterns.

The system of any preceding clause, wherein the instructions that, when executed by the computing system, are configured to cause the computing system to apply the one or more reference data patterns by: applying a median filtering to detect noise within the borehole data, wherein the one or more reference data patterns comprise a salt and pepper pattern; and detecting the one or more regions based on the detect noise having values that exceed a noise threshold.

The system of any preceding clause, wherein the instructions that, when executed by the computing system, are configured to cause the computing system to generate a sinusoid detection model based on the labeled borehole data.

The system of any preceding clause, wherein generating the sinusoid detection model comprises training the sinusoid detection model using an additional portion of the one or more regions, wherein each region of the additional portion of the one or more regions has an additional artifact score above the threshold value.

The system of any preceding clause, wherein the instructions that, when executed by the computing system, are configured to cause the computing system to determine the one or more artifact scores based on a relative area of the one or more regions.

The system of any preceding clause, wherein the one or more reference data patterns comprise a missing value pattern, a line artifact pattern, a stretching pattern, an impulse noise pattern, or a spiral pattern.

One or more tangible non-transitory computer-readable memory media, comprising: processor-executable instructions that, when executed by one or more processors, cause the one or more processors to: receive borehole data; receive one or more reference data patterns from a storage component, wherein the one or more reference data patterns correspond to one or more borehole data artifacts; apply the one or more reference data patterns to the borehole data to detect one or more regions in the borehole data that include one or more potential artifacts; determine one or more artifact scores associated with the one or more regions based on a comparison between the one or more regions and the one or more reference data patterns; generate one or more labels based on a portion of the one or more regions, wherein each of the one or more labels is indicative of a respective region of the portion of the one or more regions having an artifact score below a threshold value; and generate labeled borehole data based on the one or more labels.

The one or more tangible non-transitory computer-readable memory media of any preceding clause, wherein the instructions that, when executed by the one or more processors, are configured to cause the one or more processors to apply the one or more reference data patterns by: applying a thresholding technique to borehole data to produce a modified borehole data; identifying the one or more regions within the modified borehole data; and determining whether a shape of the one or more regions matches the one or more reference data patterns.

The one or more tangible non-transitory computer-readable memory media of any preceding clause, wherein the instructions that, when executed by the one or more processors, are configured to cause the one or more processors to generate a sinusoid detection model based on the labeled borehole data.

The one or more tangible non-transitory computer-readable memory media of any preceding clause, wherein generating the sinusoid detection model comprises training the sinusoid detection model using an additional portion of the one or more regions, wherein each region of the additional portion of the one or more regions has an additional artifact score above the threshold value.

The one or more tangible non-transitory computer-readable memory media of any preceding clause, when executed by the one or more processors, are configured to cause the one or more processors to apply the one or more reference data patterns by: applying a thresholding technique to the borehole data to generate adjusted borehole data; identifying one or more clusters of the adjusted borehole data having null values based on a missing value pattern, wherein the one or more reference data patterns comprise the missing value pattern; and detecting the one or more regions based on the one or more clusters of the adjusted borehole data having the null values.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for (perform)ing (a function) . . . ” or “step for (perform)ing (a function) . . . ”, it is intended that such elements are to be interpreted under 35 U.S.C. 112(f). However, for any claims containing elements designated in any other manner. it is intended that such elements are not to be interpreted under 35 U.S.C. 112(f).

1. A method, comprising:
receiving, via a processing system, borehole data;
receiving, via the processing system, one or more reference data patterns from a storage component, wherein the one or more reference data patterns correspond to one or more borehole data artifacts;
applying, via the processing system, the one or more reference data patterns to the borehole data to detect one or more regions in the borehole data that include one or more potential artifacts;
determining, via the processing system, one or more artifact scores associated with the one or more regions based on a comparison between the one or more regions and the one or more reference data patterns;
generating, via the processing system, one or more labels based on a portion of the one or more regions, wherein each of the one or more labels is indicative of a respective region of the portion of the one or more regions having an artifact score below a threshold value; and
generating, via the processing system, labeled borehole data based on the one or more labels.

2. The method of claim 1, further comprising generating a sinusoid detection model based on the labeled borehole data.

3. The method of claim 2, wherein generating the sinusoid detection model comprises training the sinusoid detection model using an additional portion of the one or more regions, wherein each region of the additional portion of the one or more regions has an additional artifact score above the threshold value.

4. The method of claim 1, wherein applying the one or more reference data patterns to the borehole data comprises:
applying a thresholding technique to the borehole data to generate adjusted borehole data;
identifying one or more clusters of the adjusted borehole data having null values based on a missing value pattern, wherein the one or more reference data patterns comprise the missing value pattern; and
detecting the one or more regions based on the one or more clusters of the adjusted borehole data having the null values.

5. The method of claim 1, wherein applying the one or more reference data patterns to the borehole data comprises:
applying a thresholding technique to the borehole data to generate adjusted borehole data; and
identifying the one or more regions having a shape that matches a line artifact pattern, wherein the one or more reference data patterns comprise the line artifact pattern.

6. The method of claim 1, wherein applying the one or more reference data patterns to the borehole data comprises:
applying a right-handed pattern and a left-handed pattern corresponding to a spiral pattern to the borehole data, wherein the one or more reference data patterns comprise a spiral pattern; and
detecting the one or more regions based on at least a partial match between the right-handed pattern or the left-handed pattern.

7. The method of claim 1, wherein applying the one or more reference data patterns comprises to the borehole data comprises:
predicting pattern of the borehole data based on a linear interpolation between two regions of the borehole data, wherein the one or more reference data patterns comprise a stretching pattern; and
detecting the one or more regions based on a mismatch between data of the one or more regions and the predicted pattern of the borehole data.

8. The method of claim 1, wherein applying the one or more reference data patterns to the borehole data comprises:
applying a median filtering to detect noise within the borehole data, wherein the one or more reference data patterns comprise a salt and pepper pattern; and
detecting the one or more regions based on the detect noise having values that exceed a noise threshold.

9. A system, comprising
a computing system comprises one or more processors;
a memory storing instructions that, when executed by the computing system, are configured to cause the computing system to perform operations comprising:
receiving borehole data;
receiving one or more reference data patterns from a storage component, wherein the one or more reference data patterns correspond to one or more borehole data artifacts;
applying the one or more reference data patterns to the borehole data to detect one or more regions in the borehole data that include one or more potential artifacts;
determining one or more artifact scores associated with the one or more regions based on a comparison between the one or more regions and the one or more reference data patterns;
generating one or more labels based on a portion of the one or more regions, wherein each of the one or more labels is indicative of a respective region of the portion of the one or more regions having an artifact score below a threshold value; and
generating labeled borehole data based on the one or more labels.

10. The system of claim 9, wherein the instructions that, when executed by the computing system, are configured to cause the computing system to apply the one or more reference data patterns by:
applying a thresholding technique to borehole data to produce a modified borehole data;
identifying the one or more regions within the modified borehole data; and
determining whether a shape of the one or more regions matches the one or more reference data patterns.

11. The system of claim 9, wherein the instructions that, when executed by the computing system, are configured to cause the computing system to apply the one or more reference data patterns by:
applying a median filtering to detect noise within the borehole data, wherein the one or more reference data patterns comprise a salt and pepper pattern; and
detecting the one or more regions based on the detect noise having values that exceed a noise threshold.

12. The system of claim 9, wherein the instructions that, when executed by the computing system, are configured to cause the computing system to generate a sinusoid detection model based on the labeled borehole data.

13. The system of claim 12, wherein generating the sinusoid detection model comprises training the sinusoid detection model using an additional portion of the one or more regions, wherein each region of the additional portion of the one or more regions has an additional artifact score above the threshold value.

14. The system of claim 9, wherein the instructions that, when executed by the computing system, are configured to cause the computing system to determine the one or more artifact scores based on a relative area of the one or more regions.

15. The system of claim 9, wherein the one or more reference data patterns comprise a missing value pattern, a line artifact pattern, a stretching pattern, an impulse noise pattern, or a spiral pattern.

16. One or more tangible non-transitory computer-readable memory media, comprising:
processor-executable instructions that, when executed by one or more processors, cause the one or more processors to:
receive borehole data;
receive one or more reference data patterns from a storage component, wherein the one or more reference data patterns correspond to one or more borehole data artifacts;
apply the one or more reference data patterns to the borehole data to detect one or more regions in the borehole data that include one or more potential artifacts;
determine one or more artifact scores associated with the one or more regions based on a comparison between the one or more regions and the one or more reference data patterns;
generate one or more labels based on a portion of the one or more regions, wherein each of the one or more labels is indicative of a respective region of the portion of the one or more regions having an artifact score below a threshold value; and
generate labeled borehole data based on the one or more labels.

17. The one or more tangible non-transitory computer-readable memory media of claim 16, wherein the instructions that, when executed by the one or more processors, are configured to cause the one or more processors to apply the one or more reference data patterns by:
applying a thresholding technique to borehole data to produce a modified borehole data;
identifying the one or more regions within the modified borehole data; and
determining whether a shape of the one or more regions matches the one or more reference data patterns.

18. The one or more tangible non-transitory computer-readable memory media of claim 16, wherein the instructions that, when executed by the one or more processors, are configured to cause the one or more processors to generate a sinusoid detection model based on the labeled borehole data.

19. The one or more tangible non-transitory computer-readable memory media of claim 18, wherein generating the sinusoid detection model comprises training the sinusoid detection model using an additional portion of the one or more regions, wherein each region of the additional portion of the one or more regions has an additional artifact score above the threshold value.

20. The one or more tangible non-transitory computer-readable memory media of claim 16, when executed by the one or more processors, are configured to cause the one or more processors to apply the one or more reference data patterns by:
applying a thresholding technique to the borehole data to generate adjusted borehole data;
identifying one or more clusters of the adjusted borehole data having null values based on a missing value pattern, wherein the one or more reference data patterns comprise the missing value pattern; and
detecting the one or more regions based on the one or more clusters of the adjusted borehole data having the null values.
